(19) United States
(12) Patent Application Publication
(10) Pub. No.: US 2024/0014262 A1
(43) Pub. Date: Jan. 11, 2024

(54) Semiconductor Featuring Ridged Architecture

(71) Applicant: Walter A. Tormasi, Martinsville, NJ (US)

(72) Inventor: Walter A. Tormasi, Martinsville, NJ (US)

(21) Appl. No.: 17/803,424

(22) Filed: Jul. 5, 2022

(51) Int. Cl. H01L 29/06; H01L 31/0236; H01L 31/18; H01L 21/02; G03F 7/20

(52) U.S. Cl. CPC H01L 29/0657; H01L 31/02363; H01L 31/1804; H01L 31/1808; H01L 21/02035; G03F 7/70058

(57) ABSTRACT

A semiconductor, such as crystallized silicon or germanium, features top-mounted ridges. Circuits are capable of being integrated onto the ridges using modified photolithographic processes. The ridged architecture increases the usable surface area per given footprint of semiconductors. Specifically, if the preferred embodiment is adopted, the ridges increase relative surface area by 41.42%. Such an increase in surface area has numerous advantages. One advantage is that microchip footprints can be 29.29% smaller, allowing 1.41 times more microchips to be produced per wafer. Another advantage is that solar panels can contain 1.41 times more electron-shuttling junctions, thereby increasing overall sunlight harnessing, electrical conversion, and panel efficiency by 41.42%.

### CROSS-REFERENCE TO RELATED APPLICATIONS

This patent claims priority to U.S. Provisional Patent Application No. 63/259,941, said application filed by the inventor herein, Walter A. Tormasi, on 23 Aug. 2021.

### FIELD OF THE INVENTION

The invention pertains to microchips, solar cells, photolithography, and associated subjects. The invention, accordingly, encompasses multiple fields, including semiconductors and integrated circuits. Those fields are interrelated and involve various classes and disciplines, all of which are implicated by the invention disclosed herein.

### BACKGROUND OF THE INVENTION

Given the fields involved, the invention finds its background in the microchip industry. The composition and fabrication of microchips are therefore discussed. Also discussed are the limitations of existing microchip and semiconductor technology, as an awareness of such limitations is necessary to fully recognize and understand the novelty, innovativeness, advantages, and scope of the invention.

Most high-end microchips feature millions of integrated circuits. Those integrated circuits, comprising transistors and other components, provide microchips with memory and logic capabilities. Given their function and efficiency (among other qualities), microchips are indispensable and ubiquitous. Over one billion microchips are manufactured annually. Microchips are contained within every sophisticated electronic device, ranging from computers to televisions to smartphones. Microchips, needless to say, are omnipresent in developed societies and impact the daily activities of individuals, businesses, governments, and institutions.

The first integrated circuit was experimentally developed in the 1950s. The creation and introduction of working microchips soon followed. Although microchip performance has improved over the years, no revolutionary architectural improvements have occurred. General microchip design, in other words, has remained unchanged.

Microchips rely on semiconductors to function. A semiconductor, by definition, features conductive and insulative properties. Such dual electrical properties are present in select elements and compounds. Semiconducting elements include silicon (Si) and germanium (Ge). Semiconducting compounds include indium antimonide (InSb), cadmium telluride (CdTe), and silver iodide (AgI). Silicon, however, is the most common semiconductor used for microchip manufacturing.

Microchip fabrication begins with the creation of semiconducting crystals. Because silicon crystals are prevalent in microchip manufacturing, silicon refinement and crystallization are discussed below. Different processes will necessarily apply for other semiconducting substances.

To create silicon crystals, silica is first harvested from mineral deposits. Silica, which is an abundant resource, consists of bonds of silicon and oxygen. The bonds are broken, separating the constituents. The silicon, once captured, undergoes various purification steps. The refined silicon is then contained, heated, and liquefied.

The silicon thereafter undergoes controlled contamination, known as doping. During the doping stage, select impurities (in minute quantities) are introduced into the silicon melt. The impurities, known as dopants, are evenly distributed throughout the melt. Those impurities give the silicon desired electrical and semiconducting characteristics.

Once the doping process is completed, the silicon solution is crystallized. The crystallization process is necessary to form an ordered bonding of the individual silicon atoms. The Czochralski method is commonly used to produce silicon crystals, although other methods are possible. In the microchip industry, silicon crystals are slowly grown (using seed-retraction and other methods) into cylindrical ingots. The ingots typically measure 30 centimeters in diameter. Newer foundries, however, employ larger-diameter ingots.

The cylindrical ingots are then sliced into thin wafers. Those wafers take the shape of circular discs with planar profiles. Hundreds of such wafers are produced from an individual ingot. Each silicon wafer serves as the semiconducting base from which microchips are produced.

At this point, additional doping is typically performed on the silicon wafer. Because the silicon is now solid (in crystalline form), doping is limited to alterations at the near-surface region. A common wafer-doping method is ion implantation. That process involves bombarding the wafer with ions. The ions penetrate the wafer and are implanted in the surface vicinity. The ions serve as dopants, changing the electrical and semiconducting characteristics of the wafer.

The next step involves populating the silicon wafer with integrated circuits. In the field of microchips, only one circuit-projecting method is employed. That method is photolithography, which uses radiation (photons or electrons) to transfer the desired circuit pattern to the silicon wafer.

The photolithographic process involves multiple steps, including wafer treatment, wafer masking, and wafer flashing. These steps are fairly straightforward. The wafer is first coated with photoresistive material, which contains an alkaline-soluble protective resin and radiation-sensitive stabilizing compound. A mask is horizontally positioned over the coated wafer. The mask features an inverse image of the circuits sought to be created. Radiation is beamed through the mask, causing the radiation-sensitive compound to convert into an acid. The acid decomposes the resin, exposing the wafer according to the mask-filtered radiation pattern. Additional steps are performed during the photolithographic process, including chemical etching and vacuum deposition. Such steps are performed in concert, with the end result being that metallic circuits are created on the silicon wafer.

A typical wafer features hundreds of planar-topped microchips. The microchips are square or rectangular and are arranged in gridlike fashion. Thus, after the integrated circuits are formed, the wafer is sliced into grids, separating the microchips. Because the wafer is circular, the edges of the wafer contain partial microchips. Those partial microchips, which are incomplete and therefore nonfunctional, are immediately discarded. The remaining microchips are collected, inspected, tested, packaged, and distributed accordingly.

A key metric in the microchip industry is the width and spacing of integrated circuits. Narrower circuits allow closer spacing (known as pitch). Closer circuit spacing, in turn, allows microchip footprints to be reduced, in which event more microchips can be fabricated per silicon wafer.

The microchip industry has settled on various sizing standards. Such standards include 14, 10, 7, 5, 3, and 2 nanometers. These metrics refer to the resolution, or thickness, of the photolithographic process employed. Smaller nanometer-resolutioned processes produce tinier circuits, improving manufacturing yields. Manufacturers therefore strive to employ the finest photolithographic process possible.

The laws of physics, however, limit the width and spacing of integrated circuits. All types of matter, including silicon crystals and metallic circuitry, consist of atoms. Even though most atoms are incredibly stable, all atoms are handicapped by quantum and molecular limitations. If integrated circuits become too minuscule, electrons will leak from transistors and other critical components. Lost electrons, of course, will adversely impact the integrity of integrated circuits. At the very least, electron losses will cause microchips to become unreliable, if not completely inoperable.

The microchip industry has brushed against the foregoing width/spacing limitations. Whereas photolithographic processes have shrunk consistently over the years, such shrinking has plateaued. Microchip manufacturers have been employing 5-nanometer processes for an extended period. It appears that 3-nanometer or 2-nanometer processes will be the boundary for electron leakage, preventing manufacturers from shrinking integrated circuits beyond that point.

Thus, at present or in the near future, width and spacing reductions of integrated circuits will no longer be possible. Since circuit miniaturization has reached its terminus, manufacturers cannot enjoy the benefits of further miniaturization. So unless architectural and other innovations are developed, microchip footprints (and, consequently, microchip-per-wafer yields) will remain unchanged.

### SUMMARY OF THE INVENTION

The invention has numerous objectives. The primary objective is to increase the usable surface area per given footprint of semiconductors. Through such increases in relative surface area, semiconductors can contain more circuits than previously allowed. Microchip footprints can therefore be reduced, overcoming the limitations discussed above.

The invention accomplishes surface-area increases in an unconventional manner, namely, by utilizing multiple ridges situated atop the semiconductor. The ridges, which are constructed of semiconducting material such as silicon, serve as the substrate upon which integrated circuits are formed.

Under one embodiment of the invention, the ridges are prism-shaped protrusions having side geometries of an isosceles right triangle. That geometrical structure provides advantages during the photolithographic process, as the ridge surfaces are oriented at 90-degree angles. The ridges, of course, can feature angles other than suggested.

It can be shown, mathematically, that the invention dramatically increases usable surface area. Specifically, if the preferred embodiment is adopted (that is, if the ridges have inner angles of 45, 90, and 45 degrees), then surface area can be increased by 41.42%. Such increased surface area permits microchip footprints to be 29.29% smaller, thereby allowing 1.41 times more microchips to fit on each silicon wafer.

The invention, needless to say, provides numerous benefits. By enabling smaller microchip footprints, the invention increases production yields, giving microchip manufacturers competitive advantages. Such advantages include lower microchip prices and greater profit margins.

The invention, it must be noted, goes beyond traditional microchips. Ridged architecture, for example, can be applied to photovoltaic modules (solar panels). The upshot is that 1.41 times more solar cells can be located on each photovoltaic module, increasing overall sunlight harnessing, electrical conversion, and panel efficiency by 41.42%.

The invention, in short, has wide-ranging impact and applies to all semiconductor-based technologies, not just to traditional microchips. The invention also has objects, components, and advantages other than those discussed.

### BRIEF DESCRIPTION OF THE DRAWINGS

Eighteen drawings are supplied. Four drawings depict prior art and are supplied for context purposes. The remaining drawings inclusively illustrate various aspects of the invention in connection with the preferred embodiments and best modes of implementation. Those drawings, as such, are intended to complement the disclosure without limitation.

FIG. 1 (Prior Art), FIG. 2 (Prior Art), and FIG. 3 (Prior Art) depict, in perspective and side views, an ordinary semiconducting wafer and an ordinary microchip.

FIG. 4 and FIG. 5 depict, in perspective and overhead views, the ridged semiconducting wafer as invented.

FIG. 6, FIG. 7, and FIG. 8 depict, in perspective, overhead, and side views, the ridged microchip as invented.

FIG. 9 and FIG. 10 depict, in perspective and side views, an individual ridge under the preferred embodiment.

FIG. 11 (Prior Art) depicts, in side view, the photolithographic process applicable to ordinary wafers.

FIG. 12, FIG. 13, FIG. 14, and FIG. 15 depict, in side view, modifications to the ordinary photolithographic process stemming from the ridged architecture of the invention.

FIG. 16 and FIG. 17 depict, in perspective view (as illustrated from the perspective of radiation travel during the photolithographic process), the ridged wafer as invented.

FIG. 18 depicts, in side view, an additional photolithographic process applicable to ridged wafers.

Included within the foregoing drawings are various elements, namely, planar surface 1, ridge surfaces 1a and 1b, ridge base 1c, ridge peak 2, ridge valley 3, planar mask 4, angled sectional masks 4a and 4b, and radiation beam 5.

The foregoing drawings and elements are thoroughly and comprehensively discussed in the below disclosure.

### DETAILED DESCRIPTION OF THE INVENTION

The invention, as noted above, is directed at increasing the usable surface area per given footprint of semiconductors. The invention accomplishes that objective via top-mounted ridges upon which circuits can be mounted. Because the ridges increase relative surface area, the invention, in essence, decouples the perceived unbreakable correspondence between fixed footprint and fixed usable surface area.

A detailed description is provided concerning ridge placement, ridge geometry, ridge utilization, and ridge ramifications. Also discussed are various modes for implementing and practicing the invention as claimed herein.

Before addressing the foregoing subjects, however, current wafer and microchip technology must be briefly discussed. That discussion will enable the invention to be fully delineated, contrasted, compared, and understood.

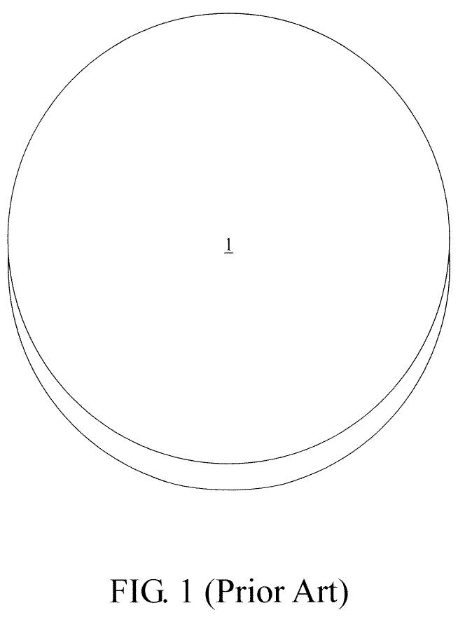

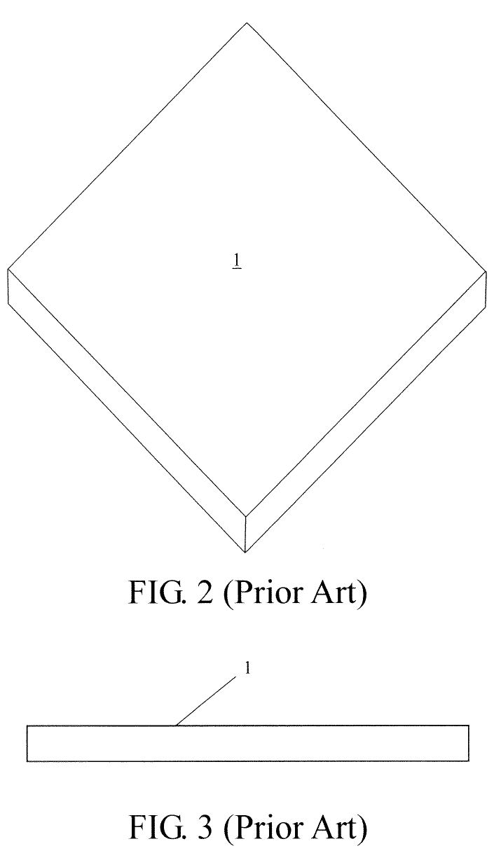

FIG. 1 (Prior Art) depicts an ordinary semiconducting wafer. FIG. 2 (Prior Art) and FIG. 3 (Prior Art) depict an ordinary microchip. FIG. 1 (Prior Art) and FIG. 2 (Prior Art) show the perspective view of the wafer and microchip, respectively, while FIG. 3 (Prior Art) shows the side view of the microchip in two-dimensional format.

As discussed previously, and as shown in FIG. 1 (Prior Art), FIG. 2 (Prior Art), and FIG. 3 (Prior Art), ordinary wafers and microchips have planar top faces. Those planar top faces are represented as surface 1 in the aforementioned prior-art illustrations. As shown therein, surface 1 (which is circuit-mountable) is substantially flat, featuring no raised or angled elements whatsoever.

The invention modifies, and improves upon, prior art through architectural and other innovations. First and foremost, the invention encompasses top-mounted ridges. Those ridges are composed of semiconducting material (crystallized silicon or germanium, for example). The ridges have conductive and insulative properties and, accordingly, serve as the substrate upon which integrated circuits can be formed.

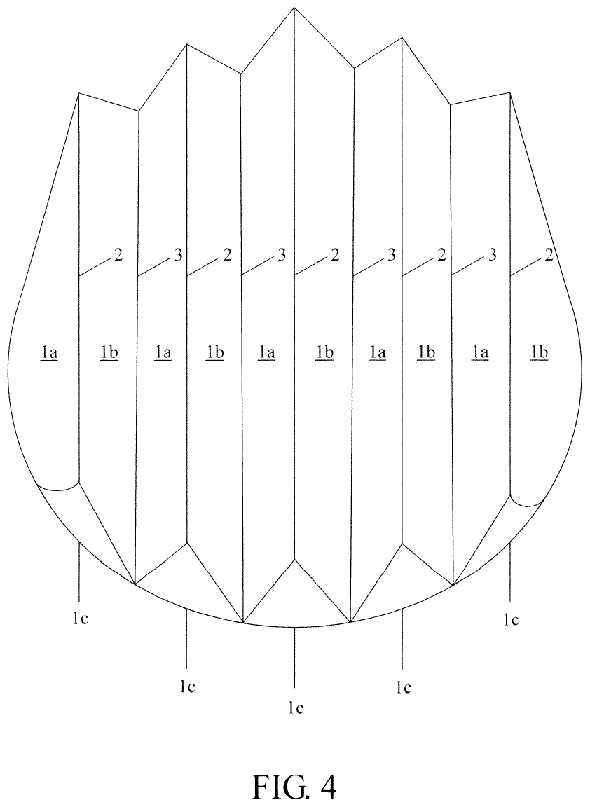

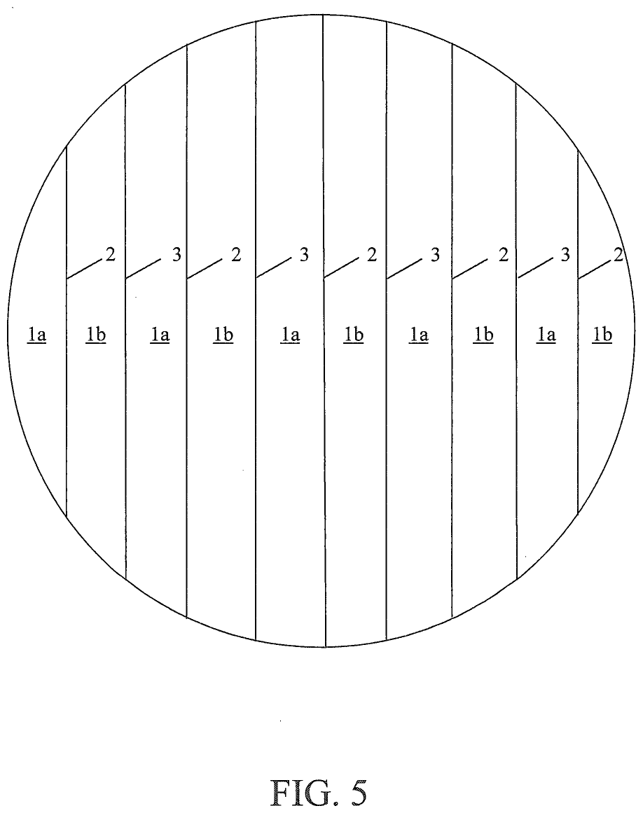

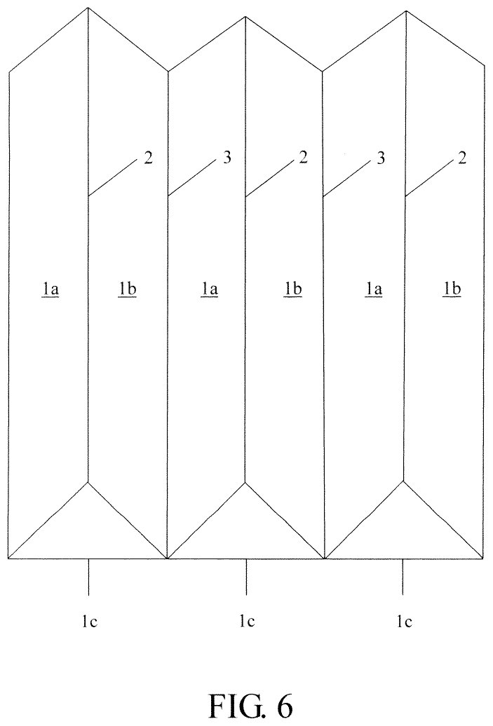

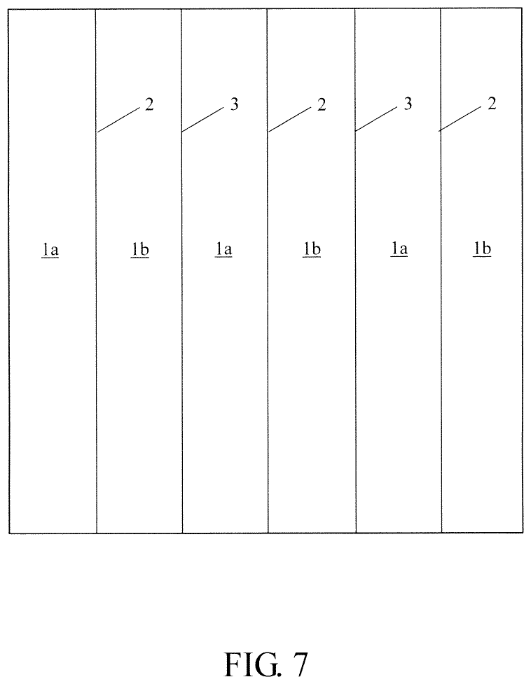

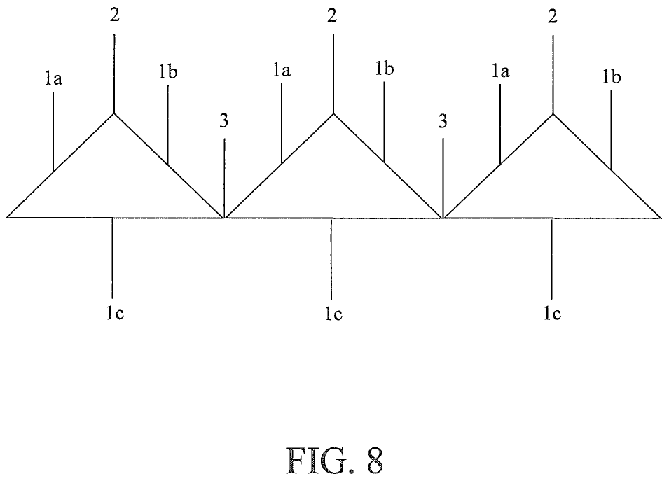

The circuit-mountable ridged architecture at issue is depicted in the next series of drawings, namely, FIGS. 4 through 8. In particular, FIG. 4 and FIG. 5 depict (in perspective and overhead views, respectively) the ridged semiconducting wafer as invented. FIG. 6, FIG. 7, and FIG. 8 depict (in perspective, overhead, and side views, respectively) the ridged microchip as invented. As shown in the aforementioned illustrations, the wafer and microchip feature top-mounted ridges. The ridges comprise five elements. Such elements consist of surface 1a, surface 1b, surface/base 1c (not visible in FIG. 5 and FIG. 7), peak 2, and valley 3.

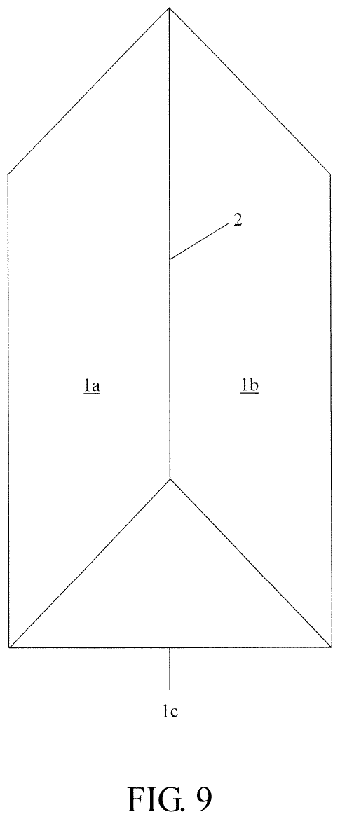

Delving more deeply, FIG. 9 depicts an individual ridge. It can be seen that the ridge is prism-shaped, as all sides of the ridge are parallel and terminate identically. A triangular shape, in turn, outlines the side of the ridge.

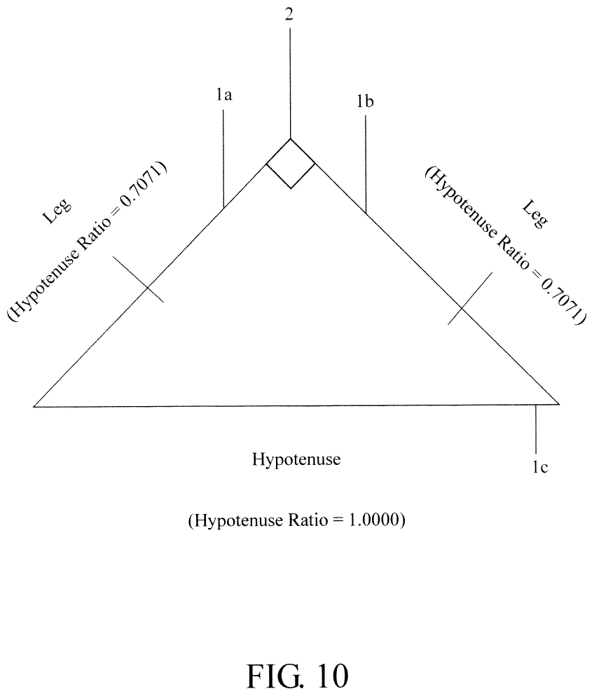

FIG. 10 depicts the ridge from the previous illustration. In contrast to FIG. 9, however, FIG. 10 depicts the ridge from its side, making the view two-dimensional. Also, in contrast to FIG. 9, FIG. 10 features generally accepted geometric indicators. Those indicators consist of an angle symbol, hash lines, leg and hypotenuse labels, and other markings. The side-viewed triangular geometry represented in FIG. 10 constitutes the preferred ridge embodiment.

Applying geometric principles to the indicators in FIG. 10, it can be discerned that the inside angle of surfaces 1a and 1b is 90 degrees. It can also be discerned that the inside angles of surfaces 1a and 1c and surfaces 1b and 1c are identical, namely, 45 degrees. The ridge, as such, features side dimensions of an isosceles right triangle, as the ridge has one right angle and two equal-length (and equal-angled) legs.

In terms of function and use, surfaces 1a and 1b (as shown in FIGS. 4 through 10, among others) constitute working surfaces. Surfaces 1a and 1b, in other words, are circuit-mountable semiconducting substrates. On the other hand, surface 1c (not shown in FIG. 5 and FIG. 7) functions as the base of the wafer and microchip. Consequently, unlike surfaces 1a and 1b, surface/base 1c is nonworking in nature.

A key aspect of the invention is an increase in the usable surface area per given footprint of semiconductors. The ridged architecture, as invented, described, and claimed, accomplishes such intended surface-area increases.

To calculate the precise surface-area increase resulting from the preferred embodiment of the invention, trigonometric principles must first be applied. As geometrically depicted in FIG. 10, surfaces 1a and 1b serve as the legs of the triangular ridge, while surface 1c serves as the hypotenuse thereof. With knowledge of the inner angles of the triangular ridge (45, 90, and 45 degrees), hypotenuse ratios can be calculated via trigonometry. It can be determined, in particular, that the hypotenuse ratio of the hypotenuse (surface 1c) is 1.000. It can further be determined that the hypotenuse ratio of each leg (surface 1a and surface 1b) is 0.7071. All such ratios are denoted parenthetically in FIG. 10.

Arithmetic now comes into play to calculate the exact surface-area increase. The combined hypotenuse ratios of surface 1a (0.7071) and surface 1b (0.7071) is 1.4142. That value signifies that surfaces 1a and 1b, collectively, are 1.4142 times longer than surface 1c. It follows, mathematically, that the ridged architecture, as structured, increases surface area by 41.42% relative to surface 1c.

At this point, it must be mentioned that the ridges may feature side geometries other than isosceles right triangles. Any triangular shape is technically possible. A change in ridge angle, however, will alter the hypotenuse ratios and thereby alter surface-area increases. A change in ridge angle will also impact the photolithographic process, as will be discussed shortly. It is therefore suggested that the ridges feature the angles and side geometries proposed.

It bears mentioning, as well, that the ridges in the accompanying illustrations are not drawn to scale in relation to the wafer or microchip. The size of the ridges in those drawings has been exaggerated solely to promote comprehensibility. Unlike the scenario depicted, the ridges are intended to be sized at the millimeter or micron scale.

By way of example, ridges can be manufactured with one-millimeter hypotenuses, in which event standard wafers (which measure 30 centimeters in diameter) will contain 300 ridges. Ridges can also be manufactured with one-micron hypotenuses, in which event standard wafers will contain 300,000 ridges. Any other ridge size can be employed, including ridge sizes falling outside the millimeter or micron scales. Precise sizing decisions, of course, belong to the manufacturer.

Regardless of the ridge size employed, the percentage of surface-area increase (namely, 41.42%) will remain. This is because increases in surface area are governed by ridge geometry, not ridge size. Thus, identical ridge angles will produce identical hypotenuse ratios and surface-area increases, regardless of the ridge size employed.

With that said, it should not be concluded that ridge size is irrelevant or inconsequential. Larger ridges will have greater volumes, requiring use of more semiconducting material. The opposite is true for smaller ridges, although the reduced-volume benefits of smaller ridges may be offset by increased implementation difficulties. These considerations, among others, should be weighed by the manufacturer in choosing whether to employ millimeter-scale or micron-scale ridges.

Once ridge geometry and size are chosen, the semiconducting wafer must be contoured accordingly. Methods of ridge creation may differ depending on ridge measurement. Where millimeter-scale ridges are employed, mechanical slicing or grinding of the wafer surface is possible. Where micron-scale ridges are employed, laser cutting/vaporization may be necessary. Other contouring methods can be utilized, whether such methods are additive or subtractive in nature.

Where necessary or feasible, ridges can also be constructed using separate crystallized semiconductors. That is, individual ridges may be composed of individual crystals, making the ridged semiconductor polycrystalline. If individual ridge crystals are employed, those crystals need not share adjoining grain boundaries. The individual crystals, instead, may be interfaced superficially (without molecular bonding), thereby preventing grain boundaries from changing the electrical and semiconducting properties of individual crystals.

In short, numerous ridge embodiments exist, giving manufacturers numerous options for creating the ridged architecture as invented. Different ridge embodiments may, of course, require different ridge-creation processes. It is the prerogative of the manufacturer to choose accordingly.

During the ridge-forming process, caution should be exercised to avoid damaging the crystalline structure of the semiconductor. Semiconducting substances such as silicon are crystallized to form specially arranged atomic bonds. The crystalline structure enables conduction and insulation, defining the character of the semiconductor. Crystal damage will therefore impact functionality and performance.

Where the crystalline structure of the semiconductor is damaged during the ridge-forming process, compensatory doping may be performed. It is known that certain structural defects in crystals produce the same effect as valence-differing donor or acceptor impurities. It is therefore possible to counteract physical crystal damage via selective doping. To induce negative charges to the semiconductor, manufacturers can employ donor impurities (such as arsenic, antimony, or phosphorus). To induce positive charges to the semiconductor, manufacturers can employ acceptor impurities (such as aluminum, boron, indium, or gallium). This process of compensatory doping allows manufacturers to counteract crystal damage sustained during the ridge-creation process.

Whether performed for compensatory or routine purposes, all post-crystallization doping can be achieved using existing techniques. The wafer-doping process, at present, is administered directly overhead. Specifically, dopants are introduced perpendicular to the wafer base via ion implantation or, for deeper penetration, ion beam mixing. That overhead bombardment procedure remains technologically viable. However, because post-crystallization doping will now be applied to angled surfaces, doping targets may need to be modified. A modification will be necessary where the doping is performed for circuit-embedding purposes, in which event doping regions must be narrowed (by 29.29% under the preferred ridge embodiment) to account for the greater area and increased number of circuits along the elongated portion of the ridge surfaces.

Once ridges are created and conditioned, integrated circuits must be formed onto their surfaces. The photolithographic process is used for that purpose. Given the ridged architecture, however, certain modifications to the normal photolithographic process will be necessary.

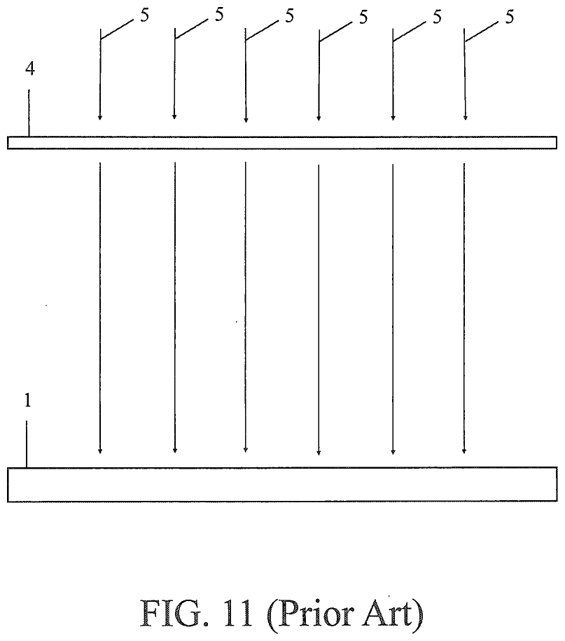

For reference purposes, FIG. 11 (Prior Art) depicts photolithographic procedures applicable to ordinary planar wafers. In that drawing, mask 4 is laterally positioned over surface 1, which represents the circuit-mountable portion of the planar wafer. The planar wafer is coated with photoresistive material. A photon or electron emitter (not shown) discharges radiation beam 5. Beam 5 passes through mask 4, thereby exposing surface 1 according to the layout of mask 4.

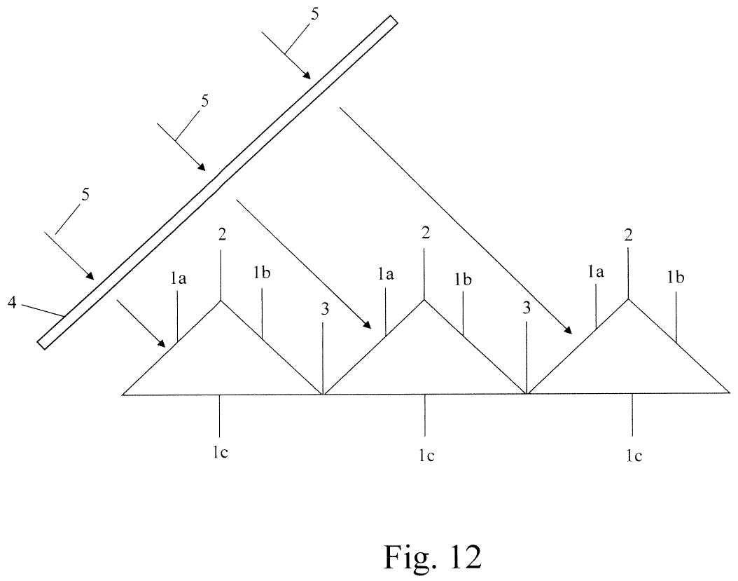

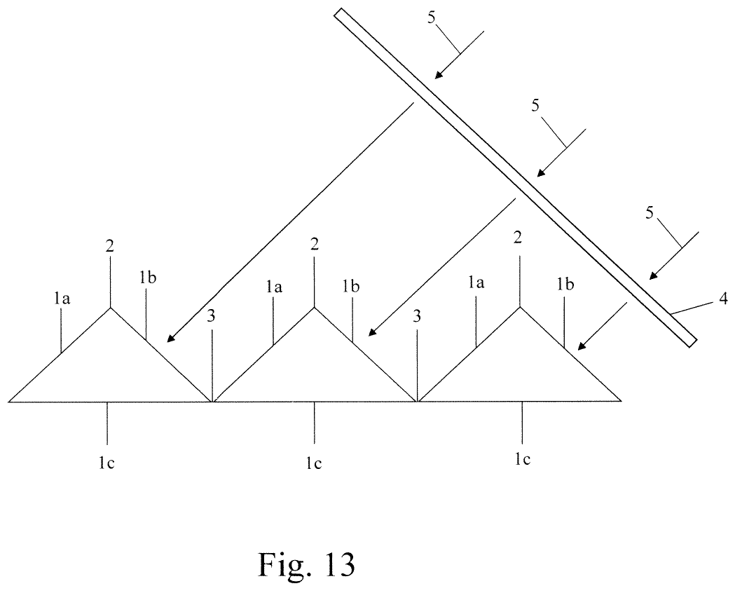

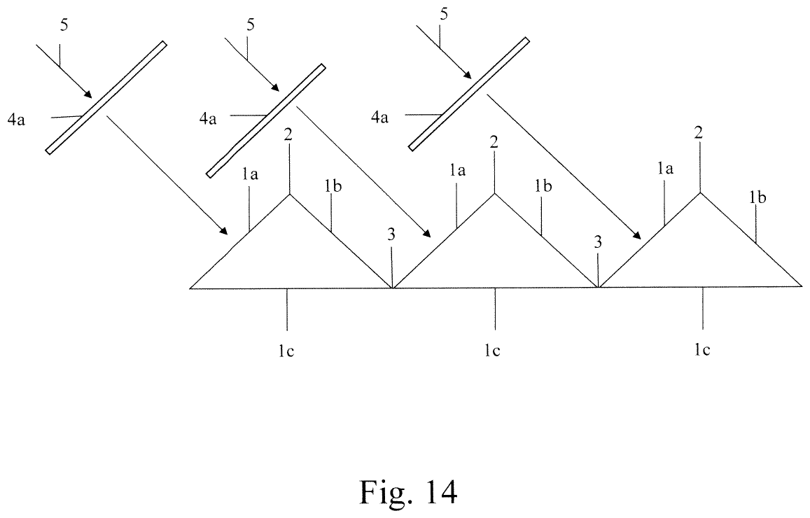

FIG. 12 and FIG. 13 depict one variation of the photolithographic process. As shown in FIG. 12, mask 4 is tilted until level with surface 1a. Radiation beam 5 passes through mask 4, exposing surface 1a. Because surface 1b is parallel with beam 5, surface 1b is shielded from exposure, thereby protecting surface 1b from beam 5. A similar scenario is depicted in FIG. 13, except that surface 1b is exposed to beam 5 while surface 1a is shielded from exposure.

FIG. 14 and FIG. 15 depict another variation of the photolithographic process. As shown in the respective drawings, mask 4a and mask 4b are divided by the number of ridges, with each subdivision being individually tilted. Mask 4a (shown in FIG. 14) is level with surface 1a, while mask 4b (shown in FIG. 15) is level with surface 1b. Unlike the prior embodiment, this embodiment has the advantage of allowing the mask to be positioned at uniform distances from surfaces 1a and 1b.

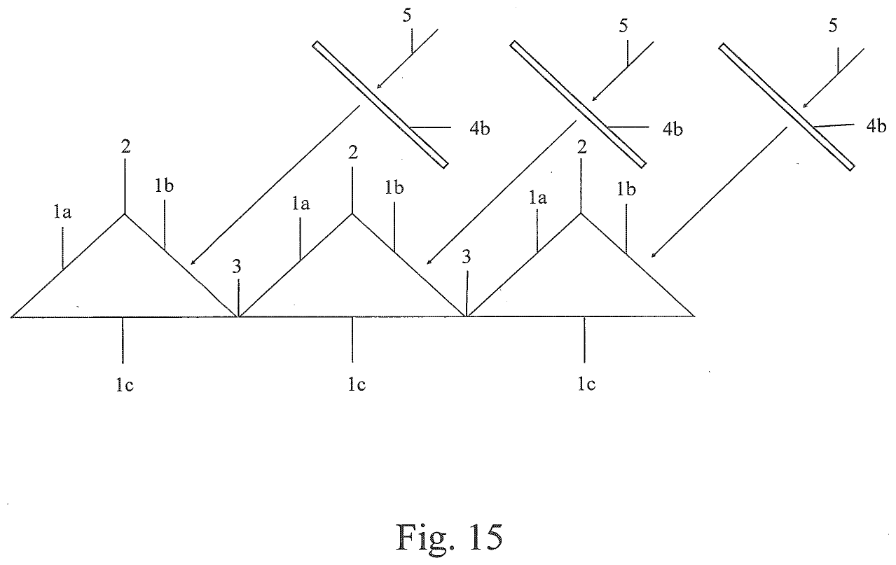

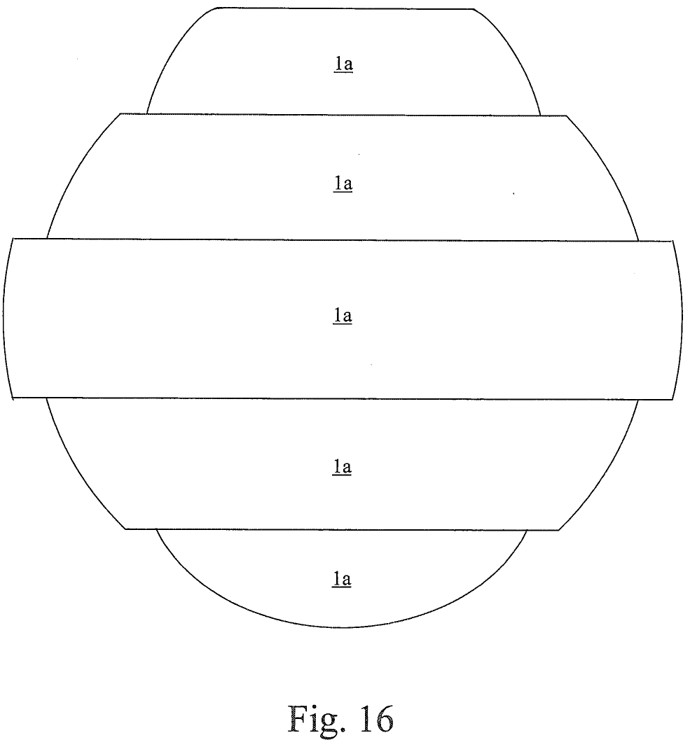

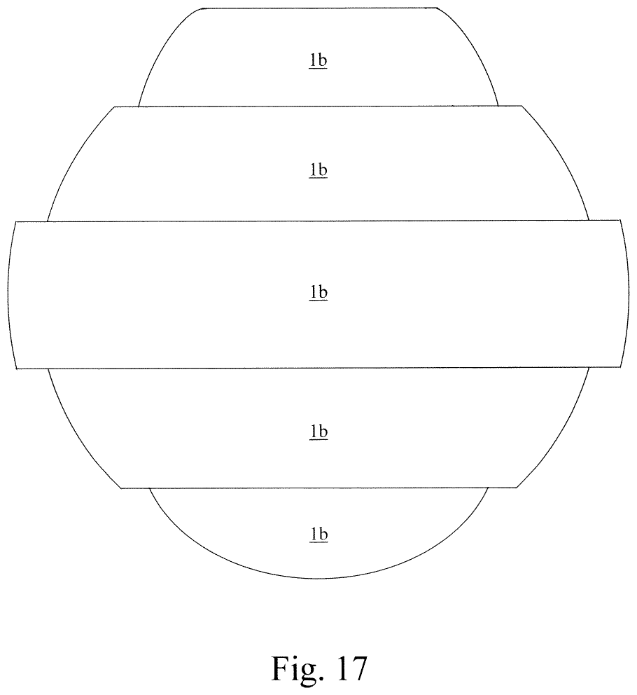

FIG. 16 and FIG. 17 further illustrate the modified photolithographic process. Each drawing depicts one circular wafer featuring five ridges. The five-ridge wafer is depicted from the perspective of the radiation beam (not shown). FIG. 16 corresponds with the photolithographic angle employed in FIGS. 12 and 14, while FIG. 17 corresponds with the photolithographic angle employed in FIGS. 13 and 15. Interpreting FIG. 16 and FIG. 17 in that context, it can be seen that surfaces 1a and 1b are either exposed or hidden, depending on the angle of the radiation beam. Specifically, because the undepicted beam in FIG. 16 is angled perpendicularly with surface 1a, only surface 1a is visible in that drawing (meaning that surface 1b is shielded). Conversely, because the undepicted beam in FIG. 17 is angled perpendicularly with surface 1b, only surface 1b is visible in that drawing (meaning that surface 1a is shielded).

At this point, the photolithographic advantages of the preferred ridge geometries should become evident. The ridges, as embodied and illustrated above, have side geometries of an isosceles right triangle. That shape orients the ridge surfaces at 90-degree angles. Given those adjacent right angles, surfaces 1a and 1b can be completely exposed or hidden, thereby streamlining the photolithographic process.

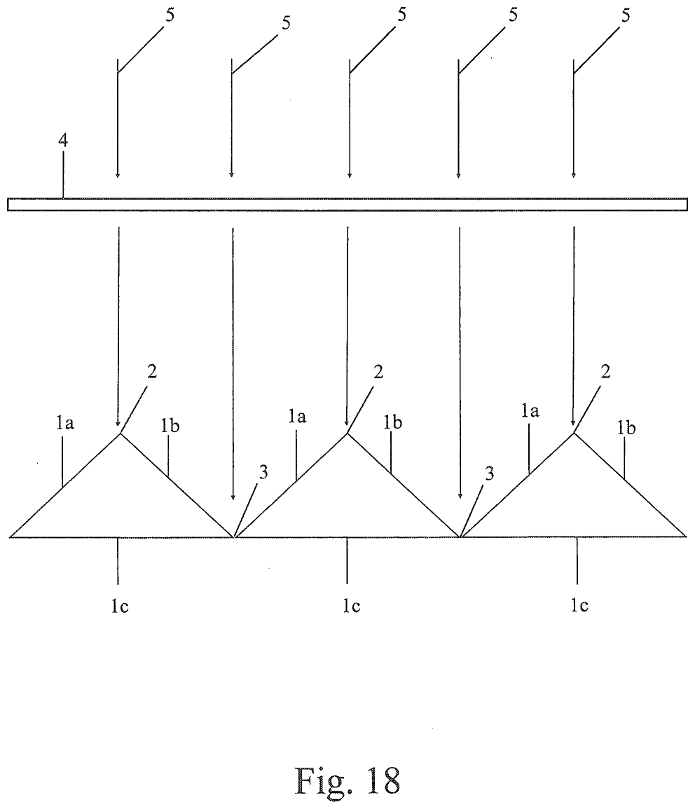

For the sake of completeness, it must be mentioned that another photolithographic step may be necessary in addition to the angled versions shown in FIGS. 12 through 15. The potential extra step stems from the ridged architecture, which features sharp-angled peaks and valleys. Circuits must be formed on those peaks and valleys to join the adjacent working surfaces. Specifically, referring to FIG. 18, peak 2 must connect with surface 1a and surface 1b, while valley 3 must connect with surface 1b and surface 1a. Any lack of connection between surface 1a and surface 1b will break the electrical continuum, preventing circuit interoperability.

FIG. 18 depicts the photolithographic process for creating joining circuits on the peaks and valleys. As shown in that drawing, mask 4 is parallel with the ridged wafer. Beam 5 passes through mask 4. Mask 4 is configured to prevent exposure of surface 1a and surface 1b. Mask 4 is also configured with the circuit layout of peak 2 and valley 3, allowing radiation beam 5 to selectively expose peak 2 and valley 3.

The procedure in FIG. 18, to reiterate, is directed at creating joining circuits on the peaks and valleys of the ridged architecture. The procedure will therefore be unnecessary if joining circuits can be created through the photolithographic modifications previously discussed.

By following the above steps, among others, skilled artisans can design and produce ridged wafers and ridged microchips according to the preferred embodiments of the invention. There are, of course, other potential embodiments and other potential manufacturing steps. For that reason, other methods and processes may be employed to implement the invention. It is believed, however, that the above steps constitute the best modes for implementing the invention.

Whatever embodiments and modes of implementation are chosen, the invention does, in fact, accomplish its primary objective. The invention, in particular, increases the usable surface area per given footprint of semiconductors. Although the amount of surface-area increase will vary depending on ridge angle and hypotenuse-to-leg ratios, it has been mathematically demonstrated that ridges having side geometries of isosceles right triangles will increase surface area by 41.42%.

The surface-area increase, as calculated, has numerous ramifications. First and foremost, an increase in surface area translates into greater heat dissipation, which is an important concern in microchip design. Aside from greater heat dissipation, however, the increase in surface area permits microchip footprints to be 29.29% smaller, allowing 1.41 times more microchips to fit on each wafer and thereby enhancing production yields. The increase in surface area also extends the life cycle of semiconductor foundries, allowing more circuits and components to be integrated per microchip using the same nanometer-resolutioned photolithographic process.

With that said, it must be emphasized that the invention and its advantages go beyond microchip-based logic and memory circuits. Ridged architecture can be applied to any semiconductor-dependent technology, including photovoltaic cells, modules, and arrays. If the invention is applied to the solar industry in accordance with the preferred embodiment, then photovoltaic devices can contain 41.42% more electron-shuttling junctions, increasing power output correspondingly.

The invention, in short, has wide-ranging impact and applies to all semiconducting devices, not just to traditional microchips. The invention also features objects, components, and advantages other than those mentioned.

What is claimed is:

1. An electronic device, said device comprising: an element or compound having semiconducting capabilities; and means for increasing the circuit-mountable area per given footprint of said semiconducting element or compound.

2. A semiconductor, said semiconductor comprising: two or more ridges, wherein said ridges are situated atop the semiconductor; wherein said ridges are capable of carrying circuits; and wherein said ridges increase the usable surface area per given footprint of the semiconductor.

3. The semiconductor of claim 2, wherein said semiconductor is constructed of crystallized silicon.

4. The semiconductor of claim 2, wherein said semiconductor is constructed of crystallized germanium.

5. The semiconductor of claim 2, wherein said ridges have side geometries of an isosceles right triangle.

6. The semiconductor of claim 2, wherein said ridges have hypotenuses measuring one millimeter or less.

7. The semiconductor of claim 2, wherein said ridges have hypotenuses measuring one micron or less.

8. The semiconductor of claim 2, wherein said ridges are composed of individual semiconducting crystals.

9. The semiconductor of claim 2, wherein said semiconductor is polycrystalline in nature.

10. The semiconductor of claim 2, wherein said semiconductor contains logic circuits.

11. The semiconductor of claim 2, wherein said semiconductor contains memory circuits.

12. The semiconductor of claim 2, wherein said semiconductor contains photovoltaic circuits.

13. A method for increasing the number of electronic circuits containable on semiconducting material, said method comprising the following steps: creating circuit-mountable ridges atop said semiconducting material; and subjecting said ridges to one or more photolithographic processes.

14. A method for increasing electrical output per given footprint of a photovoltaic cell, said method comprising the following steps: creating multiple ridges atop said photovoltaic cell to increase circuit-mountable surface area; and creating electron-shuttling junctions on the surfaces of said ridges.

15. A method for forming integrated circuits on ridged surfaces of a semiconductor, said method comprising the following steps: treating the ridged surfaces in preparation for applying circuit-creating photolithographic processes; screening the ridged surfaces using masking means; situating said masking means parallel with the surfaces of common-facing ridges; and passing radiation perpendicularly through said masking means to selectively expose the surfaces of common-facing ridges according to the circuit layout of the masking means.

16. A photolithographic system, said photolithographic system comprising: one or more radiation emitters; an element or compound having semiconducting capabilities, said element or compound featuring ridged surfaces; and masking means for selectively exposing said ridged surfaces to radiation.

17. The photolithographic system of claim 16, wherein said masking means comprises an angled unitary mask assigned to the surfaces of multiple common-facing ridges.

18. The photolithographic system of claim 16, wherein said masking means comprises multiple sectional masks situated parallel with the surfaces of common-facing ridges.

19. The photolithographic system of claim 18, wherein said sectional masks are positioned at substantially uniform distances from the surfaces of common-facing ridges.
